(19) United States
(12) Patent Application Publication
(10) Pub. No.: US 2023/0266673 A1
(43) Pub. Date: Aug. 24, 2023

(54) OPTICAL ELEMENT, IN PARTICULAR FOR REFLECTING EUV RADIATION, OPTICAL ARRANGEMENT, AND METHOD FOR MANUFACTURING AN OPTICAL ELEMENT

(71) Applicant: Carl Zeiss SMT GmbH, Oberkochen (DE)

(72) Inventor: Vitaliy SHKLOVER, Heidenheim (DE)

(21) Appl. No.: 18/309,809

(22) Filed: Apr. 30, 2023

Related U.S. Application Data
(63) Continuation of application No. PCT/EP2021/077360, filed on Oct. 5, 2021.

(30) Foreign Application Priority Data
Oct. 29, 2020 (DE) 10 2020 213 639.4

(51) Int. Cl. G03F 7/20

(52) U.S. Cl. CPC G03F 7/70175; G03F 7/70158; G03F 7/702

(57) ABSTRACT

A reflective optical element (17), in particular for reflecting EUV radiation (16), includes: a substrate (25), and a reflective coating (26) applied to the substrate (25). In one disclosed aspect, the substrate (25) is doped within its volume (V) with at least one precious metal (27). In a further disclosed aspect, the reflective coating (26) and/or a structured layer (28) that is formed between the substrate (25) and the reflective coating (26) is doped with at least one precious metal (27). Also disclosed are an optical arrangement, preferably a projection exposure apparatus for microlithography, in particular for EUV lithography, which includes at least one such reflective optical element (17), and a method of producing such a reflective optical element (17).

### CROSS-REFERENCE TO RELATED APPLICATION

This is a Continuation of International Application PCT/EP2021/077360, which has an international filing date of Oct. 5, 2021, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2020 213 639.4 filed on Oct. 29, 2020.

### FIELD OF THE INVENTION

The invention relates to a reflective optical element, in particular for reflecting extreme ultraviolet (EUV) radiation, comprising: a substrate, and a reflective coating applied to the substrate. The invention also relates to an optical arrangement, preferably for microlithography, in particular for EUV lithography, for example in the form of a projection exposure apparatus, including at least one such reflective optical element. The invention also relates to a method of producing a reflective optical element, comprising: providing a substrate, and applying a reflective coating to the substrate, said applying of the reflective coating preferably being preceded by applying of a structurable layer to the substrate and being followed by structuring, after applying.

### BACKGROUND

The optical arrangement may, for example, be an optical arrangement for EUV lithography, i.e. an optical system which can be used in the field of EUV lithography. In addition to being incorporated into a projection exposure apparatus for EUV lithography which serves for production of semiconductor components, the optical arrangement may, for example, be an inspection system for inspection of a photomask used in such a projection exposure apparatus (also referred to hereinafter as reticle), for inspection of a semiconductor substrate to be structured (also referred to hereinafter as a wafer) or a metrology system which is used for measurement of a projection exposure apparatus for EUV lithography or parts thereof, for example for measurement of a projection optical unit.

EUV lithography systems or EUV metrology systems and the components installed therein are operated in a vacuum with an addition of hydrogen at low partial pressure. The hydrogen serves to continuously clean the optical surfaces. In operation, excitation of molecular hydrogen by the EUV light generated forms hydrogen radicals (H*) and hydrogen ions (H+). Interaction of these hydrogen species with exposed surfaces of reflective optical elements (EUV mirrors), for example made from Si-containing materials (mono-/polycrystalline or amorphous silicon, quartz glass, silicon nitride, silicon carbide, in particular silicon-infiltrated silicon carbide composite (SiSiC), magnesium aluminum silicate ceramics such as cordierite ceramics, glasses or glass ceramics with very low thermal expansion, for example ULE®, Zerodur®, Clearceram® etc.) gives rise to volatile hydrides, in particular silanes, which is also referred to as HIO (“hydrogen induced outgassing”). The volatile hydrides can in turn be deposited on optical surfaces, which leads to degradation of the optical components.

The literature discloses various approaches by which the formation of volatile hydrides can be prevented or reduced.

DE102015215014A1 proposes at least partly covering the components of an EUV lithography apparatus that are exposed to the hydrogen-containing atmosphere with a protective layer of a precious metal (for example from the group of rhodium, ruthenium, iridium, palladium and platinum). The minimum thickness of the protective layer should be chosen such that the protective layer cannot be penetrated by hydrogen ions and/or hydrogen radicals.

WO2019025162A1 discloses an optical element wherein a shield separated by a gap is mounted on at least one surface region of the main body thereof, said shield providing protection from any etching effect of the surrounding hydrogen plasma. The distance between the shield and the surface region is less than twice the Debye length of the surrounding plasma. The shield may also be applied indirectly or directly to the main body. The shield may consist of a hydrogen recombination material (e.g. Ir, Ru, Pt, Pd) or have a coating of a hydrogen recombination material. The gap may be partly or completely filled with a filler material (for example aluminum oxide, zirconium nitride, yttrium oxide, cerium oxide, zirconium oxide, niobium oxide, titanium oxide, tantalum oxide, tungsten oxide, metals, preferably precious metals, in particular Ru, Rh, Pd, Ir, Pt, Au, and compositions thereof). In a further embodiment, the shield may take the form of a coating.

DE102017222690 A1 discloses an optical element for reflection of EUV radiation, having an uppermost layer of a hydrogen desorption material that has a desorption temperature for hydrogen of less than 340 K (e.g. Pd, Ag, Au and alloys thereof). In order to achieve the desired effect of releasing hydrogen, the uppermost layer need not necessarily form a continuous layer. Material accumulations of the hydrogen desorption material in the form of clusters or islands can likewise fulfill this purpose, provided that they are at a sufficiently small distance from one another.

WO2019179861 A1 discloses an EUV mirror which is exposed to a hydrogen plasma in operation, wherein the main body contains at least one material that forms at least one volatile hydride on contact of the surface region with the activated hydrogen (H+, H*). Precious metal ions (for example Rh, Ru, Ir, Au, Pd, Pt) are implanted into the main body in the surface region, in order to prevent the formation of the volatile hydride. The implantation of precious metal ions in the near-surface volume region beneath the surface can distinctly reduce the formation of volatile hydrides. This exploits the fact that precious metal ions generally have a strong catalytic effect for the recombination of activated hydrogen, i.e. of hydrogen radicals and/or of hydrogen ions, to form atomic hydrogen. By contrast with the solutions described above, there is merely doping of the main body in the implantation of the precious metal ions, but no layer formation.

However, the implantation of precious metal ions in a near-surface volume region of a main body offers only limited protection, for example when the reflective optical element is a structured optical unit. In such an optical unit, a structurable layer, for example of amorphous silicon, is applied to a substrate in order to form structuring, for example in the form of a grating structure. The grating structure may, for example, be formed on an EUV collector mirror and serve as spectral filter. Since it is very difficult to deposit complete homogeneous coverage of structured surfaces (the layer often has pores, channels or other defects or irregularities at steep edges), such a structured layer, and also silicon layers in the reflective multilayer Mo—Si layer or coating, is subjected to etching attack by reactive hydrogen species.

WO2020109225A2 has disclosed a mirror for an illumination optical unit of a projection exposure apparatus with a spectral filter in the form of a grating structure. The grating structure may be covered completely by a continuous protective layer in the form of a reflective coating having a multitude of twin Si—Mo layers. A low edge steepness of the grating structure can improve the coverage of the grating structure with the protective layer, and in this way increase the hydrogen stability of the reflective optical element.

If complete coverage of the grating structure is to be achieved even in the case of relatively high edge steepness, the reflective multilayer coating may be applied as a surface-conforming (conformal) coating, as described in WO 2013113537A2. This proposes a conformal or isotropic coating process in the form of atomic layer deposition in order to create essentially constant layer thicknesses even along a three-dimensional profile. However, the application of a reflective multilayer coating that may have more than 50 twin layers of Mo and Si by atomic layer deposition is very complex.

DE 10 2019 212 910.2 describes an optical element having a protective layer system having a first layer, a second layer and a third layer. Metallic particles and/or ions may be implanted into at least one layer of the protective layer system. The ions may be metal ions, for example precious metal ions, in particular platinum metal ions. At least one layer of the protective layer system may have been doped with metallic (nano)particles, for example with (foreign) atoms in the form of precious metal particles (e.g. Pd, Pt, Rh, Ir). The precious metal ions or foreign atoms can serve as hydrogen and/or oxygen blockers.

All the approaches described above envisage large-area processing of three-dimensional objects in complicated form, which is associated with a considerable level of complexity.

### SUMMARY

It is an object of the invention to provide a reflective optical element, an optical arrangement, and a method of producing an optical element, which enable protection from reactive species, in particular from reactive hydrogen species, said protection being implemented with a low level of complexity.

This and other objects are achieved, in its first aspect, by an optical element of the type specified at the outset, in which the substrate is doped within its volume with at least one precious metal.

The inventor has recognized that doping of the substrate material with a hydrogen recombination material in the form of a precious metal can be effected much more efficiently even during the process of producing the substrate than is the case via subsequent implantation of precious metal ions in a near-surface volume region, as described in WO2019179861 A1, cited at the outset.

By contrast with the main body described therein, the doping with the precious metal in the case of the reflective optical element of the invention is not limited to a near-surface volume region having an implantation depth of less than 1000 nm. The substrate is instead doped with the precious metal within the volume as well, i.e. also in a volume region having a distance from the surface of the substrate of more than 1000 nm, for example of more than 1 mm, 2 mm, 5 mm, etc. In particular, the substrate may have been doped with the precious metal throughout its volume.

In one embodiment, the substrate is formed from a glass or a glass ceramic having very low thermal expansion, for example titanium-doped quartz glass (ULE®), Zerodur®, Clearceram® etc., a ceramic, for example a silicon nitride ceramic, a silicon carbide ceramic, a silicon carbonitride ceramic, a magnesium aluminum silicate ceramic, in particular a cordierite ceramic, or from a composite material, in particular silicon-infiltrated silicon carbide composite (SiSiC). In principle, it is possible to dope any of the substrate materials used in EUV lithography with a precious metal.

The substrate is preferably formed from silicon, in particular from monocrystalline, quasi-monocrystalline or polycrystalline silicon, or optionally from amorphous silicon. Silicon doped with precious metals in the form of gold (cf. the article “Properties of Gold-Doped Silicon”, C. B. Collins et al., Phys. Rev. 105 (1957) 1168-1173) or in the form of platinum is commercially available, and can thus be used for the production of the substrate of the reflective optical element. Gold- or platinum-saturated monocrystalline silicon finds applications, for example, in microwave technology as a window for high-powered generators (cf. the article “Radiation effects on dielectric losses of Au-doped silicon”, J. Molla et al., Journal of Nuclear Materials, 258-263 (1998) 1884-1888) or in radiation detectors (cf. the article “Gold and Platinum Doped Radiation Resistant Silicon Diode Detectors”, R. L. Dixon et al., Radiation Protection Dosimetry 17 (1986) 527-530).

Monocrystalline silicon is additionally a popular material for production of substrates for x-ray, EUV and synchrotron optics; the polishing technology for this purpose has been mastered. Useful methods in the production of monocrystalline silicon are all conventional methods, such as the Czochralski method (cf. “Ein neues Verfahren zur Messung der Kristallisations-geschwindigkeit der Metalle” [A Novel Method of Measuring the Rate of Crystallization of Metals], J. Czochralski, Zeitschrift fur physikalische Chemie, 92 (1918) 219-221) or the Bridgeman-Stockbarger method (cf. “Certain Physical Properties of Single Crystals of Tungsten, Antimony, Bismuth, Tellurium, Cadmium, Zinc, and Tin”, P. W. Bridgeman, Proceedings of the American Academy of Arts and Sciences 60 (1925) 305-383). These methods are also suitable for production of gold- or platinum-saturated monocrystalline silicon.

For particularly large crystals, Schott Solar AG has developed a method of producing quasi-monocrystalline silicon (DE102012100147 A1, DE102012102597 A1), based on the vertical gradient freeze method (VGF method). This method, or the VGF method, is suitable for production of gold- or platinum-saturated quasi-monocrystalline silicon.

A further aspect of the invention relates to a reflective optical element of the type specified at the outset, which can in paticular be combined with the reflective optical element of the first aspect of the invention. The reflective optical element comprises a structured layer which is formed between the substrate and the reflective coating, and which preferably forms or has a grating structure, wherein the structured layer is doped with (at least) one precious metal.

As described above, the reflective coating may form a protective layer for the structured layer, which prevents or at least limits the etching attack of reactive hydrogen species and hence the outgassing of volatile hydrides. If the flanks of the grating structure have an excessive flank steepness of more than 60°, for example, however, the structured layer is generally no longer fully covered by the reflective coating, unless it is applied in a complex isotropic coating method, for example by atomic layer deposition.

The doping of the structured layer, which may be formed, for example, from amorphous silicon (cf. WO2020109225A2, cited at the outset), with a precious metal that serves as hydrogen recombination material can nevertheless protect the structured layer from attack by hydrogen. In order to bring about the doping with the precious metal, it is possible to use a sputtering target doped with the precious metal in the applying of the structured or a structurable layer by sputtering deposition, as described in detail below.

A further aspect of the invention relates to a reflective optical element of the type specified at the outset, which can in particular be combined with the reflective optical element in the first aspect and/or the second aspect, and in which the reflective coating, in particular at least one silicon layer of a reflective Mo-Si coating, is doped with a precious metal.

In particular when the reflective coating is applied to a structured layer or when the reflective coating itself is structured and forms a grating structure, for example, there may be underetching of individual layers of the reflective coating, as shown, for example, in the article “Multilayer EUV optics with integrated IR suppression gratings”, T. Feigl et al., Proceedings of 2016 EUVL Workshop (P69), Berkeley, Jun. 13-16, 2016. The underetching in this case typically takes place at the lateral flanks of the (structured) reflective coating, typically at individual layers of the reflective coating that are particularly prone to etching attack.

In one development, the structured layer and/or the reflective coating contains silicon doped with the precious metal. As described above, the material of the structured layer may, for example, be amorphous silicon, which can be structured in a comparatively simple manner. If the reflective coating is a multilayer coating as used for the reflection of EUV radiation at normal angles of incidence (less than 45°), this—depending on the operating wavelength for which the reflective coating is designed—may have alternating layers (twin layers) of Mo and Si. As described above, silicon can form volatile silanes on contact with hydrogen. The formation of silanes can be prevented or at least reduced by the doping of the Si layers of the reflective Mo—Si coating with the precious metal. The reflective coating, more specifically individual layers of the reflective coating, may already be doped with the precious metal on deposition if a precious metal-doped sputtering target is used in a sputtering deposition (see below).

In the case of doping of silicon with a precious metal, no significant increase in the absorption of the doped silicon is to be expected at the dopant concentrations used with preference (see below), and so the doping can achieve an improvement in HIO resistance and radiation resistance with a low level of effort.

In a further embodiment, the reflective coating forms a multilayer coating for reflection of EUV radiation. Such a multilayer coating typically has a multitude of alternating layers of a material having a high real part of the refractive index at the operating wavelength and a material having a low real part of the refractive index at the operating wavelength. The materials may, for example, be silicon and molybdenum, but other material combinations are possible depending on the operating wavelength.

In a further embodiment, the precious metal is selected from the group comprising: Ru, Rh, Pd, Ag, Os, Ir, Pt, Au and combinations or alloys thereof. As described above, precious metals generally have a strong catalytic effect for the recombination of activated hydrogen, i.e. of hydrogen radicals and/or of hydrogen ions, to form molecular hydrogen. As likewise described above, it is in particular possible to use Pt- or Au-doped silicon, since this is commercially available. However, it will be apparent that it is also possible to dope other materials that form or are present in the volume of a substrate, a structured layer and/or a reflective coating with precious metals.

In a further embodiment, a dopant concentration of the precious metal in the volume of the substrate, in the structured layer and/or in the reflective coating is between 1010 cm⁻³ and 10²⁰ cm⁻³, preferably between 10¹² cm⁻³ and 10¹⁶ cm⁻³. The stated dopant concentrations enable doping of the structured layer of the reflective coating with a precious metal, for example with Au or Pt, without resulting in any significant increase in absorption of EUV radiation. The above-specified range of values of the dopant concentration has also been found to be favorable for the doping of the substrate.

In a further embodiment, the reflective optical element takes the form of a collector mirror for an illumination optical unit of a projection exposure apparatus. Such a collector mirror may have, for example, one or more ellipsoidal and/or hyperboloid reflection surfaces corresponding to the surface having the reflective coating. Illumination radiation may be incident on the reflection surface of the collector mirror with grazing incidence (GI), i.e. at angles of incidence of greater than 45°, or with normal incidence (NI), i.e. at angles of incidence of less than 45°.

The collector mirror typically has a structured layer in the form of a grating structure which serves as a spectral filter in order to suppress extraneous light, i.e. radiation at wavelengths outside the EUV wavelength range, for example in the infrared wavelength range. It will be apparent that the reflective optical element need not necessarily take the form of a collector mirror, but may also be any other reflective optical element.

A further aspect of the invention relates to an optical arrangement, preferably a projection exposure apparatus for microlithography, in particular for EUV lithography, comprising: at least one reflective optical element as described above. Such a projection exposure apparatus comprises an illumination optical system for transfer of illumination radiation from a radiation source onto a reticle comprising structures to be imaged, and a projection optical unit for imaging the structures of the reticle on a wafer. The reflective optical element may be disposed in the illumination optical system, but may also be disposed in the projection optical system.

As described above, the reflective optical element is disposed in such a projection exposure apparatus in a vacuum environment with an addition of hydrogen at low partial pressure. In the operation of the projection exposure apparatus, the interaction with the EUV radiation gives rise to reactive hydrogen species. Through the doping of the substrate, of the structured layer and/or of the reflective coating with the precious metal, it is possible at a low level of cost and inconvenience to achieve both improved HIO resistance and radiation resistance of the substrate, of the structured layer and/or of the reflective coating.

A further aspect of the invention relates to a method of the type specified at the outset, in which the reflective coating and/or the structurable layer is/are applied by sputtering deposition, wherein a sputtering target doped with a precious metal is used in the sputtering deposition, preferably containing silicon.

In the sputtering deposition, a solid-state material (sputtering target) is bombarded with high-energy ions. This detaches particles or atoms from the sputtering target, which are converted to the gas phase and are deposited on a body (substrate) to be coated. In order that the atoms detached from the sputtering target reach the substrate, the sputtering deposition typically takes place in a process chamber in which there is a high vacuum. The high-energy ions may, for example, be noble gas ions, in particular argon ions. There exist multiple variants of sputtering deposition.

In DC voltage sputtering deposition, a DC voltage is applied between the sputtering target and the substrate in order to create a plasma and to accelerate the positively charged noble gas ions to the sputtering target (cathode) and the negatively charged particles that are struck out of the sputtering target to the substrate (anode). In magnetron sputtering, a magnetic field is superimposed on the electrical field, in order to increase the ionization rate. Further variants of sputtering deposition by which the deposition is likewise possible are, for example, HF sputtering, reactive sputtering, ion beam sputtering or atom beam sputtering.

As described above, a sputtering target that serves for sputtering deposition of a layer to be structured or of layers of the reflective coating may be doped with a precious metal. For this purpose, it is possible to produce, for example, sputtering targets of gold- or platinum-doped silicon, and to use them for the sputtering deposition of structurable layers or of reflective coatings. It is possible here to exploit the fact that gold- or platinum-doped silicon is commercially available. But it will be apparent that the sputtering target may also be doped with other precious metals.

A further aspect of the invention relates to a method of the type specified at the outset, which can in particular be combined with the above-described method. In the method, the substrate which is provided for subsequent coating is doped within its volume with at least one precious metal. In this case, the substrate is already doped with the at least one precious metal in the course of production, and the doped substrate is provided for the coating.

In this aspect, the coating with the reflective coating and optionally with the structurable layer can likewise be effected with the aid of a sputtering target doped with a precious metal, but this is not necessarily the case. In particular in the case that the reflective optical element does not have a structured or structurable layer, it is possible to apply a conventional reflective coating, not doped with a precious metal, to the substrate.

It will be apparent that the reflective optical element need not necessarily be designed to reflect radiation in the EUV wavelength range, but may also be designed for reflection of radiation in other wavelength ranges, for example for reflection of radiation in the very ultraviolet (VUV) wavelength range.

Further features and advantages of the invention will be apparent from the description of working examples of the invention that follows, with reference to the figures of the drawing, which show details associated with the invention, and from the claims. The individual features may be implemented separately or in a plurality combinations as varients of the invention.

### BRIEF DESCRIPTION OF THE DRAWINGS

Working examples are shown in the schematic drawing and are detailed in the description which follows. The figures show:

FIG. 1 a schematic in meridional section of a projection exposure apparatus for EUV lithography,

FIG. 2 a schematic diagram of a reflective optical element of the projection exposure apparatus of FIG. 1, with a substrate doped with a precious metal,

FIG. 3 a schematic diagram analogous to FIG. 2, in which the reflective optical element has a structured layer doped with a precious metal, and

FIG. 4 a schematic diagram of a sputtering deposition system with a sputtering target doped with a precious metal.

### DETAILED DESCRIPTION

In the description of the drawings that follows, identical reference signs are used for components that are analogous or the same or have an analogous or the same function.

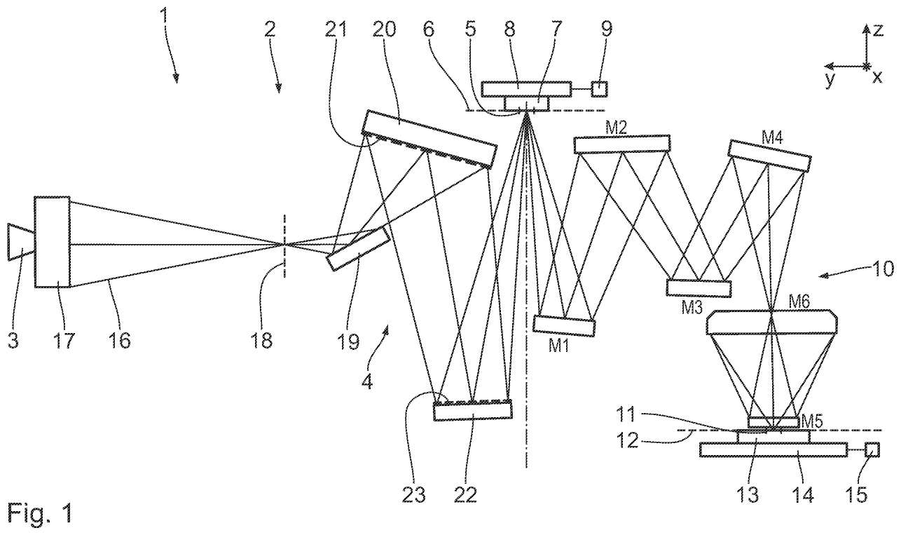

The predominant constituents of a projection exposure apparatus 1 for microlithography are described hereinafter by way of example with reference to FIG. 1. The description of the basic setup of the projection exposure apparatus 1 and constituents thereof should not be considered here to be restrictive.

An illumination system 2 of the projection exposure apparatus 1, as well as a radiation source 3, has an illumination optical unit 4 for illumination of an object field 5 in an object plane 6. What is exposed here is a reticle 7 disposed in the object field 5. The reticle 7 is held by a reticle holder 8. The reticle holder 8 is displaceable by way of a reticle displacement drive 9, in particular in a scanning direction.

For purposes of explanation, a Cartesian xyz coordinate system is shown in FIG. 1. The x direction runs perpendicularly to the plane of the drawing. The y direction runs horizontally, and the z direction runs vertically. The scanning direction runs in they direction in FIG. 1. The z direction runs perpendicularly to the object plane 6.

The projection exposure apparatus 1 comprises a projection optical unit 10. The projection optical unit 10 serves for imaging the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is configured to displace by way of a wafer displacement drive 15, especially in the y direction. The displacement of the reticle 7 on the one hand by way of the reticle displacement drive 9 and of the wafer 13 on the other hand by way of the wafer displacement drive 15 may be synchronized with one another.

The radiation source 3 is an EUV radiation source. The radiation source 3 emits EUV radiation 16 in particular, which is also referred to below as used radiation or illumination radiation. In particular, the used radiation has a wavelength in the range of between 5 nm and 30 nm. The radiation source 3 may be a plasma source, for example an LPP (“laser produced plasma”) source or a GDPP (“gas discharged produced plasma”) source. It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on at least one reflection surface of the collector mirror 17 with grazing incidence (GI), i.e. at angles of incidence of greater than 45° , or with normal incidence (NI), i.e. at angles of incidence of less than 45°. The collector mirror 17 may be structured and/or coated, firstly to optimize its reflectivity for the used radiation and secondly to suppress extraneous light.

The illumination radiation 16 propagates through an intermediate focus in an intermediate focal plane 18 downstream of the collector mirror 17. The intermediate focal plane 18 may constitute a separation between a radiation source module, having the radiation source 3 and the collector mirror 17, and the illumination optical unit 4.

The illumination optical unit 4 comprises a deflection mirror 19 and, arranged downstream thereof in the beam path, a first facet mirror 20. The first facet mirror 20 comprises a multiplicity of individual first facets 21, which are also referred to as field facets below. FIG. 1 depicts only some of these facets 21 by way of example. In the beam path of the illumination optical unit 4, a second facet mirror 22 is arranged downstream of the first facet mirror 20. The second facet mirror 22 comprises a plurality of second facets 23.

The illumination optical unit 4 consequently forms a doubly faceted system. This basic principle is also referred to as fly's eye integrator. With the aid of the second facet mirror 22, the individual first facets 21 are imaged into the object field 5. The second facet mirror 22 is the last beam-shaping mirror or actually also the last mirror for the illumination radiation 16 in the beam path upstream of the object field 5.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are similarly possible. The penultimate mirror M5 and the last mirror M6 each have a passage opening for the illumination radiation 16. The projection optical unit 10 is a double-obscured optical unit. The projection optical unit 10 has an image-side numerical aperture which is greater than 0.5 and which can also be greater than 0.6 and, for example, can be 0.7 or 0.75.

Just like the mirrors of the illumination optical unit 4, the mirrors Mi can have a highly reflective coating for the illumination radiation 16.

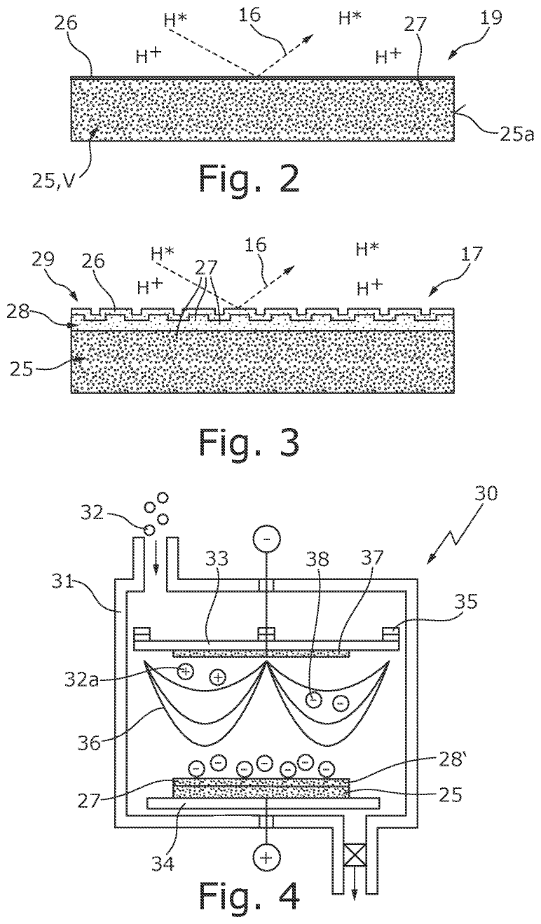

FIG. 2 shows the deflecting mirror 19 of the illumination optical system 4, having a substrate 25 of monocrystalline silicon to which a reflective coating 26 for reflection of the illumination radiation 16 is applied. The deflecting mirror 19 is exposed to reactive hydrogen species in the form of hydrogen ions (H+) and hydrogen radicals (H*). The reactive hydrogen species H+, H* may react with silicon material of the substrate 25 at exposed, for example lateral, surfaces 25a of the substrate 25, and form volatile hydrides, for example in the form of silanes. The volatile hydrides may in turn be deposited on optical surfaces, which leads to degradation thereof.

In order to counteract the formation of volatile hydrides, the substrate 25 of the deflecting mirror 19, in the example shown in FIG. 2, is doped throughout its volume V with a precious metal 27, more specifically with gold. The precious metal 27 in the form of gold atoms implanted into the silicon substrate 25 serves as hydrogen recombination material, and has the effect that the reactive hydrogen species H+, H* react to give molecular hydrogen, and therefore counteracts the formation of volatile hydrides.

The doping of the substrate 25 with the gold atoms has been effected in the production of the monocrystalline silicon substrate 25. The monocrystalline silicon substrate 25 has been pulled from the melt in the production thereof (Czochralski method). The material of the melt from which the substrate 25 has been pulled was doped here with the precious metal 27. It is likewise possible to produce the monocrystalline silicon substrate 25 doped with a precious metal 27 in other ways, for example with the aid of the Bridgeman-Stockbarger method. It is also possible to produce a quasi-monocrystalline silicon substrate 25 or a polycrystalline silicon substrate doped with a precious metal, for example with gold.

It is likewise possible to dope the silicon substrate 25 with other precious metals, for example with Ru, Rh, Pd, Ag, Os, Ir, Pt and combinations or alloys thereof. The doping of the silicon substrate 25 with Au or with Pt has been found to be favorable, since materials of this kind are already commercially available. However, it is of course likewise possible to dope the silicon substrate 25 with at least one precious metal other than Au or Pt.

The doping of the substrate 25 with a precious metal as described above can also be undertaken in the case of other substrate materials that are suitable for the production of reflective optical elements for EUV lithography. These substrate materials are, for example, quartz glass, glasses or glass ceramics having very low thermal expansion, for example ULE®, Zerodur®, Clearceram® etc., ceramics, e.g. silicon nitride, silicon carbide, in particular silicon-infiltrated silicon carbide composite (SiSiC), magnesium aluminum silicate ceramics such as cordierite ceramics, etc. It will be apparent that the doping of the substrate 25 can also be undertaken with two or more different precious metals 27.

FIG. 3 shows, by way of example, the collector mirror 17 of the illumination optical unit 2 of the projection exposure apparatus 1 of FIG. 1. The collector mirror 17 differs from the deflecting mirror 19 shown in FIG. 2 in that a structured layer 28 is formed between the substrate 25 and the reflective coating 26. The structured layer 28 has a structured surface in the form of a grating structure 29 and is formed from amorphous silicon. The grating structure 29 serves as spectral filter for suppression of extraneous light, i.e. of radiation at wavelengths outside the EUV wavelength range, for example in the infrared wavelength range. The reflective coating 26 is applied to the structured layer 28 or to the grating structure 29.

In principle, the structured layer 28 is protected from the reactive hydrogen species H+, H* by the reflective coating 26 applied. In the example shown in FIG. 3, however, the (maximum) edge steepness of the grating structure 29 is high and is about 90°. The applying of the reflective coating 26 in the form of a continuous layer that fully covers the structured layer 28 is possible even in the case of such a great edge steepness when the applying is effected by an isotropic coating method, for example by atomic layer deposition. However, the applying of the reflective coating 26, which, in the example shown, forms a multilayer coating with a number of about 50 twin layers of Si/Mo with the aid of an isotropic coating method is very complex. In addition, the collector mirror 17 is not planar, as shown in FIG. 3, but typically has an ellipsoidal or hyperboloid curvature, which additionally makes it difficult to achieve coating by atomic layer deposition.

In the example shown, the reflective coating 26 is applied to the structured layer 28 by a non-isotropic coating method, more specifically by sputtering deposition. The structured layer 28 is doped with a precious metal 27 for protection from reactive hydrogen species H+, H*. The same applies to the reflective coating 26 applied to the structured layer 28, since this, or more specifically the silicon-containing layers thereof, is likewise exposed to reactive hydrogen species H+, H*, in particular along the steep flanks of the grating structure 29. It is possible to apply a protective layer system (not shown in the figure) to the reflective coating 26, in which a precious metal may likewise be implanted in one or more layers.

For efficient performance of the doping of the structured layer 28, of the reflective coating 26 and optionally of one or more layers of the protective layer system, sputtering deposition is conducted, in which a sputtering target 37 doped with a precious metal 27 is used, as described hereinafter with reference to FIG. 4.

FIG. 4 shows, in highly simplified form, a sputtering deposition system 30 having a process chamber 31 in which there is a high vacuum. The process chamber 31 is supplied with a noble gas 32 in the form of argon via a gas inlet. The noble gas 32 enters the process chamber 31 in an interspace between a cathode 33 in plate form and an anode 34 in plate form, in which an electrical field constant over time is generated. For the generation of the electrical field, a voltage which is constant over time is applied between the cathode 33 and the anode 34. Magnets 35 that are disposed on a side of the cathode 33 remote from the interspace generate a magnetic field 36 in the interspace in addition to the electrical field.

The noble gas 32 is ionized in the interspace between the cathode 33 and the anode 34, and forms noble gas ions 32a that are accelerated to the cathode 33 and strike negatively charged particles 38 out of a sputtering target 37 mounted there, which are accelerated in the direction of the anode 34 and are deposited on a substrate 25 of the reflective optical element 17 that is mounted there.

The sputtering target 37 in the example shown is formed from monocrystalline or quasi-monocrystalline silicon doped with a precious metal 27. The effect of the doping is that a structurable layer 28′ deposited on the substrate 25 in the sputtering deposition likewise has doping with the precious metal 27. In a corresponding manner, it is also possible to deposit the reflective coating 26, or more specifically the silicon layers of the reflective coating 26, with the aid of a silicon sputtering target 37 doped with a precious metal 27.

Before the reflective coating 26 is applied, the structurable layer 28′ is structured in order to form the structured layer 28 with the grating structure 29. The structuring can be effected, for example, with the aid of a dry- or wet-chemical etching process on the structurable layer 28′ using a structuring layer. The structuring layer that serves as sacrificial layer may be structured, for example, with the aid of a lithographic exposure or in some other way.

A dopant concentration of the precious metal 27 in the volume V of the substrate 25, in the structured layer 28 and in the reflective coating 26 is typically in an order of magnitude between 10¹⁰ cm⁻³, and 10²⁰ cm⁻³, in particular between 10¹² cm⁻³ and 10¹⁶ cm⁻³. In the case of such a dopant concentration, there is no expectation of a significant increase in the absorption of the doped silicon in the reflective coating 26 or in the structured layer 28 or the substrate 25, and so the doping described here can achieve, at low cost and inconvenience, improved HIO resistance and radiation resistance of the reflective optical element 17.

It will be apparent that the doping with the precious metal 27 need not necessarily be effected both in the substrate 25 and in the structured layer 28, and in the reflective coating 26. For example, it is possible to dispense with doping of the substrate 25 if it is protected from the reactive hydrogen species in some other way. Such protection can be achieved, for example, with a shield as described in WO2019025162A1, cited at the outset, which is incorporated into this application in its entirety by reference. It may also be the case that doping of the structured layer 28 is not required if it is covered completely by the reflective coating 26.

1. A reflective optical element, comprising:
a substrate defining a volume, and
a reflective coating applied to the substrate, wherein the substrate is doped within the volume with at least one precious metal in a volume region that extends from a surface of the substrate to a distance from the surface of the substrate of more than 1 mm.

2. (canceled)

3. The reflective optical element as claimed in claim 1, wherein the substrate is formed from glass or from a composite material.

4. The reflective optical element as claimed in claim 3, wherein the glass is titanium-doped quartz glass, a glass ceramic, a ceramic, a silicon carbide ceramic, a silicon carbonitride ceramic, a magnesium aluminum silicate ceramic, or a cordierite ceramic.

5. The reflective optical element as claimed in claim 4, wherein the ceramic is a silicon nitride ceramic, a silicon carbide ceramic, a silicon carbonitride ceramic, a magnesium aluminum silicate ceramic, or wherein the composite material is silicon-infiltrated silicon carbide composite, SiSiC.

6. The reflective optical element as claimed in claim 1, wherein the substrate is formed from silicon.

7. The reflective optical element as claimed in claim 6, wherein the substrate is formed from monocrystalline, quasi-monocrystalline or polycrystalline silicon.

8. The reflective optical element as claimed in claim 1, wherein the volume region in which the substrate is doped with the at least one precious metal extends from a surface of the substrate to a distance from the surface of the substrate of more than 2 mm.

9. The reflective optical element as claimed in claim 1, wherein the volume region in which the substrate is doped with the at least one precious metal extends from the surface of the substrate to a distance from the surface of the substrate of more than 5 mm.

10. The reflective optical element as claimed in claim 1, wherein the substrate is doped with the at least one precious metal throughout the volume.

11. A reflective optical element, comprising:
a substrate defining a volume,
a reflective coating applied to the substrate, and
a structured layer formed between the substrate and the reflective coating, wherein the structured layer is doped with at least one precious metal.

12. The reflective optical element according to claim 11, wherein the structured layer forms a grating structure.

13. The reflective optical element according to claim 1, wherein the reflective coating is doped with the at least one precious metal.

14. The reflective optical element as claimed in claim 11, wherein the structured layer and/or the reflective coating contains silicon that is doped with the precious metal.

15. The reflective optical element as claimed in claim 1, wherein the reflective coating forms a multilayer coating for reflection of extreme ultraviolet (EUV) radiation.

16. The reflective optical element as claimed in claim 1, wherein the at least one precious metal is selected from the group consisting of: Ru, Rh, Pd, Ag, Os, Ir, Pt, and Au.

17. The reflective optical element as claimed in claim 1, wherein a dopant concentration of the at least one precious metal is between 10¹⁰ cm⁻³ and 10²⁰ cm⁻³.

18. The reflective optical element as claimed in claim 1 and configured as a collector mirror for an illumination optical system of a projection exposure apparatus.

19. An optical arrangement configured as at least one of a projection exposure apparatus for microlithography or a lithography apparatus for EUV radiation, comprising:
at least one reflective optical element as claimed in claim 1.

20. A method of producing a reflective optical element, comprising:
providing a substrate, and
applying a reflective coating to the substrate, wherein
the reflective coating is applied by sputtering deposition, and wherein the sputtering deposition comprises using a sputtering target doped with a precious metal.

21. A method of producing a reflective optical element, comprising:
providing a substrate, applying a structurable layer to the substrate, and applying a reflective coating to the substrate,
wherein the reflective coating and/or the structurable layer are/is applied by sputtering deposition, and wherein the sputtering deposition comprises using a sputtering target doped with a precious metal.

22. The method according to claim 21,
wherein said applying of the reflective coating is preceded by said applying of the structuable layer, and
wherein said applying of the reflective coating precedes a structuring of the structuable layer.

23. The method as claimed in claim 20, wherein the substrate defines a volume and is doped within the volume with at least one precious metal.

24. The method as claimed in claim 20, wherein the sputtering target comprises silicon.

25. A reflective optical element, comprising:
a substrate defining a volume, and
a reflective coating applied to the substrate, wherein the reflective coating is doped with at least one precious metal.
